(19) United States
(12) Patent Application Publication
(10) Pub. No.: US 2007/0222068 A1
(43) Pub. Date: Sep. 27, 2007

(54) Semiconductor device having multilayered interconnection structure formed by using Cu damascene method, and method of fabricating the same

(75) Inventor: Masaki Yamada, Saitama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/699,585

(22) Filed: Jan. 30, 2007

(30) Foreign Application Priority Data
Mar. 27, 2006 (JP) 2006-085663

(51) Int. Cl. H01L 23/48

(52) U.S. Cl. 257/734

(57) ABSTRACT

Disclosed are a semiconductor device having a multilayered interconnection structure formed by using a Cu damascene method, and a method of fabricating the same. A Cu interconnection is buried on a first barrier metal layer in a trench formed in the surface of an insulating film. An interlayer dielectric film is formed on the insulating film, first barrier metal layer, and Cu interconnection, and a hole is formed in a position corresponding to the Cu interconnection. An Al-based interconnection is electrically connected to the Cu interconnection in the hole of the interlayer dielectric film. A stacked film is interposed at least between the Cu interconnection and Al-based interconnection. This stacked film includes a second barrier metal layer for preventing the reaction between Cu and Al, and a third barrier metal layer for increasing the fluidity of Al with respect to the second barrier metal layer.

### CROSS-REFERENCE TO RELATED APPLICATIONS

This application is based upon and claims the benefit of priority from prior Japanese Patent Application No. 2006-085663, filed Mar. 27, 2006, the entire contents of which are incorporated herein by reference.

### BACKGROUND OF THE INVENTION

1. Field of the Invention

The present invention relates to a semiconductor device having a multilayered interconnection structure formed by using a Cu damascene method and a method of fabricating the same and, more particularly, to a semiconductor device in which an Al interconnection formed at a high temperature is connected on a Cu interconnection and a method of fabricating the same.

2. Description of the Related Art

Recently, a large-scale integrated circuit (LSI) formed by connecting and integrating, on one chip, a large number of elements such as transistors and resistors so as to form an electrical circuit is often used in an important portion of a computer or communication apparatus. Accordingly, the performance of the whole apparatus largely depends upon the performance of the LSI. The performance of an individual LSI can improve by increasing the integration degree, i.e., by micropatterning elements.

As the integration degree of LSIs is increasing, however, the problem that high-speed operations of elements are hindered by the RC delay caused by the increase in wiring resistance or the capacitive coupling between interconnections is becoming serious. That is, with the advancing micropatterning of elements, the wiring resistance increases as the line width decreases, and the capacitive coupling also increases due to the increase in inter-line capacitance resulting from the decrease in line pitch. As a consequence, the RC delay increases, and the operating speed of the circuit decreases.

It is, therefore, necessary to reduce the wiring resistance and inter-line capacitance, and demand has arisen for introducing a material having a low resistivity and an insulating film material having a small dielectric constant. As the interconnection material, Cu having a resistivity lower by about 35% than that of Al is beginning to be used instead of Al.

A Cu interconnection (e.g., Jpn. Pat. Appln. KOKAI Publication No. 2000-269213) formed by the damascene method has a resistivity lower by about 35%. In addition, the ratio occupied by a barrier metal layer in the interconnection is low. This makes the ratio of the rise in wiring resistance caused by micropatterning lower than that of an Al interconnection. It is being studied to apply a Cu interconnection having these characteristics to various LSIs in addition to a system LSI whose performance has improved significantly. Another merit of Cu is an electromigration resistance higher than that of Al.

Unfortunately, Cu very readily oxidizes. This oxidation progresses not only in a high-temperature ambient in which the oxygen concentration is not controlled, but also in an atmospheric ambient at room temperature. This characteristic is unfavorable in a bonding process in which contact bonding is performed at a high temperature. Therefore, a bonding electrode material such as Al must be formed on the uppermost Cu interconnection layer. The formation of this electrode material requires the same number of steps as in the interconnection formation process. For example, when a Cu interconnection is applied to an LSI which is conventionally formed by two interconnection layers, the number of steps for forming three interconnection layers is necessary. This increases the cost and prolongs the fabrication period.

Accordingly, an interconnection structure is proposed in which a Cu interconnection is formed as a first layer serving as a fine interconnection, and an Al interconnection is formed as a second layer and used as a bonding electrode, thereby reducing the wiring resistance by the cost and fabrication period for forming two interconnection layers (Jpn. Pat. Appln. KOKAI Publication No. 2003-257969).

To implement this interconnection structure, a high film formation temperature (about 400° C.) is necessary to bury Al in a fine via hole. If Al is formed at a high temperature, however, Cu and Al react with each other to significantly raise the wiring resistance, or the elevation of Cu deteriorates the reliability of the Cu interconnection.

### BRIEF SUMMARY OF THE INVENTION

According to an aspect of the present invention, there is provided a semiconductor device comprising an insulating film formed on a substrate, a Cu interconnection buried on a first barrier metal layer in a trench formed in a surface of the insulating film, an interlayer dielectric film formed on the insulating film, the first barrier metal layer, and the Cu interconnection, and including a hole in a position corresponding to the Cu interconnection, an Al-based interconnection electrically connected to the Cu interconnection in the hole of the interlayer dielectric film, and a stacked film interposed at least between the Cu interconnection and the Al-based interconnection, and comprising a second barrier metal layer to prevent a reaction between Cu and Al, and a third barrier metal layer to increase a fluidity of Al with respect to the second barrier metal layer.

According to another aspect of the present invention, there is provided a semiconductor device fabrication method comprising forming a Cu interconnection on a first barrier metal layer in a trench formed in an insulating film on a substrate, forming a film which prevents oxidation and diffusion of Cu on the insulating film, the first barrier metal layer, and the Cu interconnection, forming an interlayer dielectric film on the film which prevents oxidation and diffusion of Cu, forming a hole which exposes the Cu interconnection in positions, which correspond to the Cu interconnection, of the interlayer dielectric film and the film which prevents oxidation and diffusion of Cu, forming, in the hole, a second barrier metal layer to prevent a reaction between Cu and Al, forming a third barrier metal layer to increase a fluidity of Al with respect to the second barrier metal layer, on a surface of the second barrier metal layer in the hole, forming Al at a temperature of 325° C. to 450° C. such that Al is buried on the third barrier metal layer in the hole, and forming an Al-based interconnection by patterning the Al-based film, the third barrier metal layer, and the second barrier metal layer.

According to still another aspect of the present invention, there is provided a semiconductor device fabrication method comprising forming a Cu interconnection on a first barrier metal layer in a trench formed in an insulating film on a substrate, forming, on the Cu interconnection, a second barrier metal layer to prevent oxidation and diffusion of Cu, forming an interlayer dielectric film on the second barrier metal layer and the insulating film, forming a hole which exposes the second barrier metal layer in positions, which correspond to the Cu interconnection, of the second barrier metal layer and the interlayer dielectric film, forming, in the hole, a third barrier metal layer to increase a fluidity of Al, forming Al at a temperature of 325° C. to 450° C. such that Al is buried on the third barrier metal layer in the hole, and forming an Al-based interconnection by patterning the Al-based film and the third barrier metal layer.

### BRIEF DESCRIPTION OF THE SEVERAL VIEWS OF THE DRAWING

FIG. 1 is a sectional view for explaining a semiconductor device and a method of fabricating the same according to the first embodiment of the present invention, in which the first step of a multilayered interconnection structure fabrication method is shown;

FIG. 2 is a sectional view for explaining the semiconductor device and the method of fabricating the same according to the first embodiment of the present invention, in which the second step of the multilayered interconnection structure fabrication method is shown;

FIG. 3 is a sectional view for explaining the semiconductor device and the method of fabricating the same according to the first embodiment of the present invention, in which the third step of the multilayered interconnection structure fabrication method is shown;

FIG. 4 is a sectional view for explaining the semiconductor device and the method of fabricating the same according to the first embodiment of the present invention, in which the fourth step of the multilayered interconnection structure fabrication method is shown;

FIG. 5 is a sectional view for explaining a semiconductor device and a method of fabricating the same according to the second embodiment of the present invention, in which the first step of a multilayered interconnection structure fabrication method is shown;

FIG. 6 is a sectional view for explaining the semiconductor device and the method of fabricating the same according to the second embodiment of the present invention, in which the second step of the multilayered interconnection structure fabrication method is shown;

FIG. 7 is a sectional view for explaining the semiconductor device and the method of fabricating the same according to the second embodiment of the present invention, in which the third step of the multilayered interconnection structure fabrication method is shown;

FIG. 8 is a sectional view for explaining the semiconductor device and the method of fabricating the same according to the second embodiment of the present invention, in which the fourth step of the multilayered interconnection structure fabrication method is shown;

FIG. 9 is a sectional view for explaining the semiconductor device and the method of fabricating the same according to the second embodiment of the present invention, in which the fifth step of the multilayered interconnection structure fabrication method is shown;

FIG. 10 is a sectional view showing an application of the interconnection structures explained in the first and second embodiments, in which a memory cell portion is illustrated; and

FIG. 11 is a graph showing the relationship between the film thickness of a minimum barrier metal layer on a Cu interconnection and the resistance rising ratio after an accelerated test.

### DETAILED DESCRIPTION OF THE INVENTION

### First Embodiment

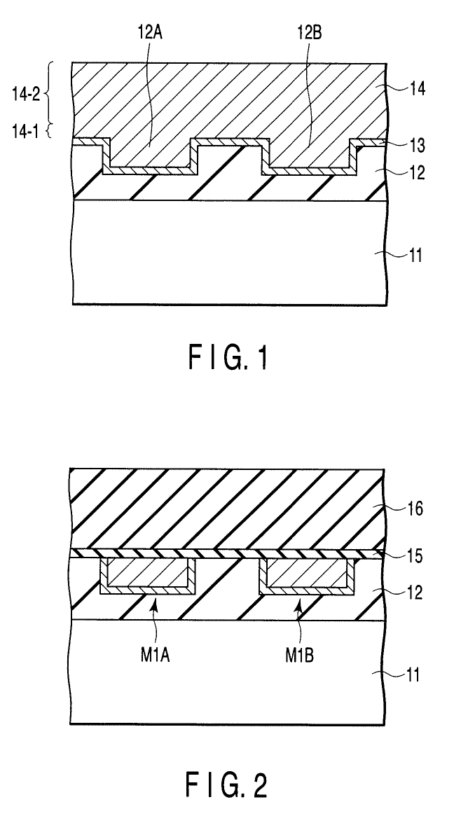

FIGS. 1 to 4 are sectional views for explaining a semiconductor device and a method of fabricating the same according to the first embodiment of the present invention, in which a method of fabricating a multilayered interconnection structure is shown in order of steps.

FIGS. 1 to 4 illustrate only steps directly related to a method of forming two metal interconnection layers, by omitting steps of forming an element isolation region and MOSFET. Also, the first embodiment will be explained by taking an example in which a buried Cu interconnection (damascene method) is used, and an Al interconnection is formed on this Cu interconnection.

First, as shown in FIG. 1, a first interlayer dielectric film 12 serving as an insulating isolation layer for a semiconductor element and lower interconnection layer (not shown) is deposited on a semiconductor substrate 11. After that, interconnection trenches 12A and 12B to be filled with an interconnection metal are formed in the surface of the interlayer dielectric film 12 by using photolithography and dry etching, in order to form a first metal interconnection layer. Then, a first barrier metal layer 13 and Cu film 14 are sequentially deposited on the interlayer dielectric film 12, thereby forming a first metal interconnection layer. The formation of this metal interconnection layer is performed by, e.g., sputtering a Ta film about 10 nm thick as the first barrier metal layer 13, forming a Cu film 14-1 about 60 nm thick without exposure to the atmosphere, and forming a plating Cu film 14-2 about 800 nm thick on the Cu film 14-1.

Then, as shown in FIG. 2, unnecessary portions of the Cu films 14-1 and 14-2 and first barrier metal layer 13 on the interlayer dielectric film 12 except for those in the interconnection trenches 12A and 12B are removed by a method such as chemical mechanical polishing (CMP). After that, an SiN film 15 as a film for preventing oxidation and diffusion of Cu is deposited on all the surfaces of the Cu film 14-2, first barrier metal layer 13, and first interlayer dielectric film 12 in the interconnection trenches 12A and 12B. Subsequently, a second interlayer dielectric film 16 is deposited on the entire surface of the SiN film 15. In this manner, first metal interconnection layers (Cu interconnections) M1A and M1B are formed as they are buried on the first barrier metal layer 13 in the interconnection trenches 12A and 12B formed in the surface of the interlayer dielectric film 12.

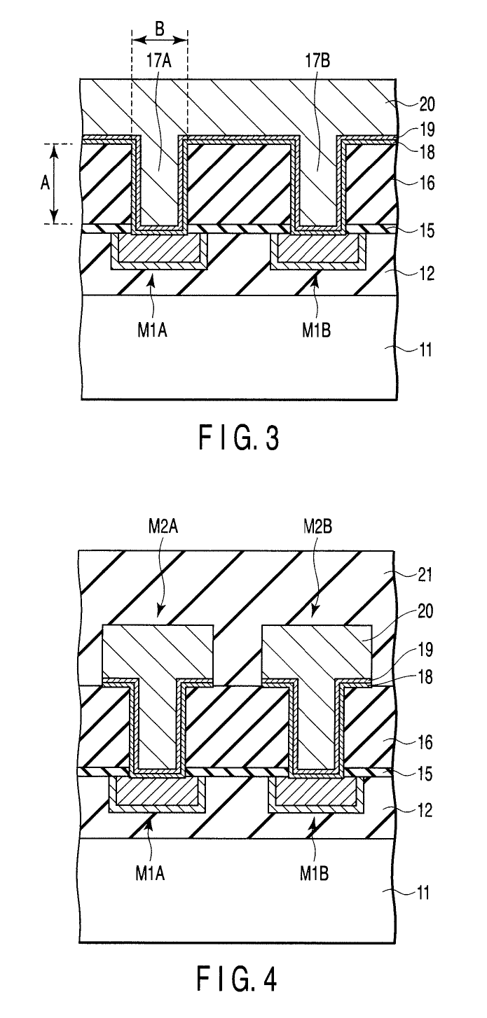

As shown in FIG. 3, holes 17A and 17B are formed in those positions of the second interlayer dielectric film 16 and SiN film 15, which correspond to the first metal interconnection layers M1A and M1B. The holes 17A and 17B respectively connect the first metal interconnection layers M1A and M1B to second metal interconnection layers M2A and M2B to be formed later. The opening size (diameter) of the holes 17A and 17B in the second interlayer dielectric film 16 is smaller than 0.3 μm. The ratio (A/B) of a thickness A of the second interlayer dielectric film 16 to an opening diameter B is larger than 1.0. After that, a second barrier metal layer 18 which prevents the reaction between Cu and Al and a third barrier metal layer 19 which increases the fluidity of Al with respect to the second barrier metal layer 18 are formed on the second interlayer dielectric film 16, on the side walls of the holes 17A and 17B, and on the Cu film 14-2, and an AlCu(0.5%) 20 is so formed as to completely fill the holes 17A and 17B. For example, the second and third barrier metal layers 18 and 19 and AlCu(0.5%) 20 are formed as follows. First, a Ta film about 15 nm thick is formed as the second barrier metal layer 18, and a Ti film about 15 nm thick is successively formed as the third barrier metal layer 19 on this Ta film without exposure to the atmosphere. After that, a film mainly containing Al, e.g., the AlCu(0.5%) 20 is formed at a high temperature of about 400° C. without exposure to the atmosphere. The barrier metal layers 18 and 19 are desirably formed by, e.g., bias sputtering or CVD. These methods can form a film having a film thickness close to the film thickness to be obtained, so no large film thickness need be set. This makes it possible to form the stacked film of the Ta film and Ti film about 15 nm thick each on the Cu film 14-2 before the Al-Cu film is formed.

As shown in FIG. 4, a photoresist is used as a mask to pattern the AlCu(0.5%) 20, third barrier metal layer 19, and second barrier metal layer 18 by dry etching, thereby forming second metal interconnection layers (Al-based interconnections) M2A and M2B. After that, a third interlayer dielectric film 21 serving as a surface protective film is deposited on the entire surface.

In the interconnection structure and fabrication method as described above, the stacked film of the barrier metal layer 18 which prevents the reaction between Cu and Al and the barrier metal layer 19 which increases the fluidity of Al with respect to the barrier metal layer 18 is formed between the Cu film 14-2 of the first metal interconnection layers (Cu interconnections) M1A and M1B and the AlCu(0.5%) 20 of the second metal interconnection layers (Al-based interconnections) M2A and M2B. Accordingly, it is possible to prevent the reaction between Al and Cu when the AlCu(0.5%) 20 is formed at a high temperature, and improve the burying properties of Al-Cu. Also, before the high-temperature formation of the AlCu(0.5%) 20, the barrier metal layers 18 and 19 about 15 nm thick each are formed on the Cu film 14-2. This makes it possible to suppress elevation when the Al—Cu film is formed. It is also possible to prevent deterioration of the reliability by stress migration.

### Second Embodiment

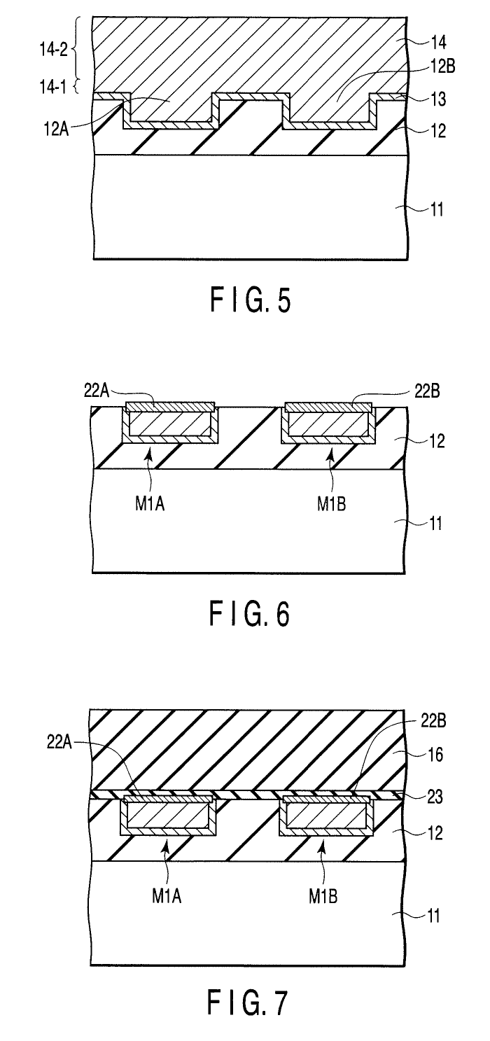

FIGS. 5 to 9 are sectional views for explaining a semiconductor device and a method of fabricating the same according to the second embodiment of the present invention, in which a method of fabricating a multilayered interconnection structure is shown in order of steps.

FIGS. 5 to 9 illustrate only steps directly related to a method of forming two metal interconnection layers, by omitting steps of forming an element isolation region and MOSFET. Similar to the first embodiment, the second embodiment will be explained by taking an example in which a buried Cu interconnection is used, and an Al-based interconnection is formed on this Cu interconnection.

First, as shown in FIG. 5, a first interlayer dielectric film 12 serving as an insulating isolation layer for a semiconductor element and lower interconnection layer (not shown) is deposited on a semiconductor substrate 11. After that, interconnection trenches 12A and 12B to be filled with an interconnection metal are formed in the surface of the interlayer dielectric film 12 by using photolithography and dry etching, in order to form a first metal interconnection layer. Then, a first barrier metal layer 13 and Cu film 14 are sequentially deposited on the interlayer dielectric film 12, thereby forming a first metal interconnection layer. The formation of this metal interconnection layer is performed by sputtering a Ta film about 10 nm thick as the first barrier metal layer 13, forming a Cu film 14-1 about 60 nm thick without exposure to the atmosphere, and forming a plating Cu film 14-2 about 800 nm thick on the Cu film 14-1.

Then, as shown in FIG. 6, unnecessary portions of the Cu films 14-1 and 14-2 and barrier metal layer 13 on the interlayer dielectric film 12 except for those in the interconnection trenches 12A and 12B are removed by a method such as chemical mechanical polishing (CMP). After that, second barrier metal layers 22A and 22B about 20 nm thick as films for preventing oxidation and diffusion of Cu are deposited on only the Cu film 14-2 in the interconnection trenches 12A and 12B. In this manner, first metal interconnection layers (Cu interconnections) M1A and M1B on the upper surfaces of which the second barrier metal layers 22A and 22B are formed are buried on the first barrier metal layer 13 in the interconnection trenches 12A and 12B formed in the surface of the interlayer dielectric film 12.

As shown in FIG. 7, an etching stopper 23 is deposited on all the surfaces of the second barrier metal layers 22A and 22B and first interlayer dielectric film 12. A second interlayer dielectric film 16 is deposited on the entire surface of the etching stopper 23.

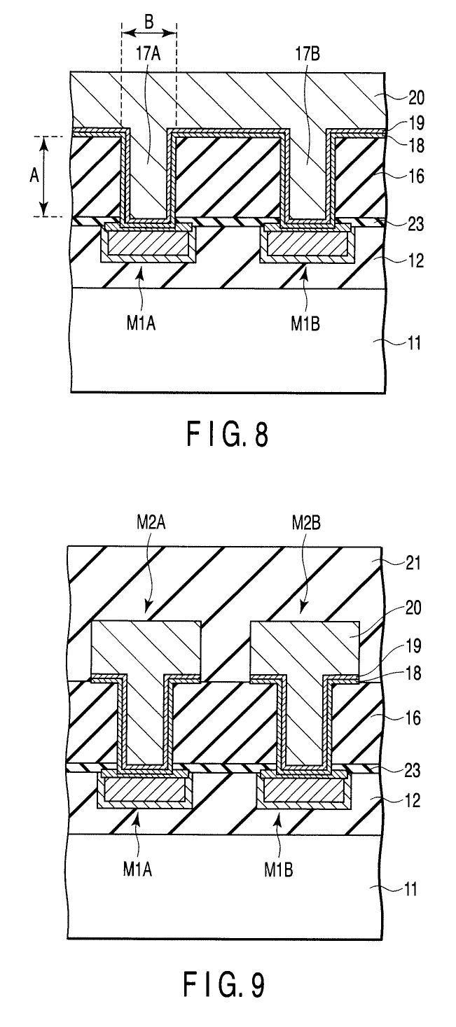

As shown in FIG. 8, holes 17A and 17B are formed in those positions of the second interlayer dielectric film 16 and etching stopper 23, which correspond to the first metal interconnection layers M1A and M1B. The holes 17A and 17B respectively connect the first metal interconnection layers M1A and M1B to second metal interconnection layers M2A and M2B to be formed later. The opening size (diameter) of the holes 17A and 17B in the second interlayer dielectric film 16 is smaller than 0.3 μm. The ratio (A/B) of a thickness A of the second interlayer dielectric film 16 to an opening diameter B is larger than 1.0. After that, a third barrier metal layer 18 which prevents the reaction between Cu and Al and a fourth barrier metal layer 19 which increases the fluidity of Al with respect to the third barrier metal layer 18 are formed on the second interlayer dielectric film 16, on the side walls of the holes 17A and 17B, and on the second barrier metal layers 22A and 22B, and an AlCu(0.5%) 20 is so formed as to completely fill the holes 17A and 17B. The third and fourth barrier metal layers 18 and 19 and AlCu(0.5%) 20 are formed as follows. First, a Ta film about 10 nm thick is formed as the third barrier metal layer 18, and a Ti film about 15 nm thick is successively formed as the fourth barrier metal layer 19 on this Ta film without exposure to the atmosphere. After that, a film mainly containing Al, e.g., the AlCu(0.5%) 20 is formed at a high temperature of about 400° C. without exposure to the atmosphere. The barrier metal layers 18 and 19 are desirably formed by, e.g., bias sputtering or CVD. These methods can form a film having a film thickness close to the film thickness to be obtained, so no large film thickness need be set.

As shown in FIG. 9, a photoresist is used as a mask to pattern the AlCu(0.5%) 20, fourth barrier metal layer 19, and third barrier metal layer 18 by dry etching, thereby forming second metal interconnection layers (Al-based interconnections) M2A and M2B. After that, a third interlayer dielectric film 21 serving as a surface protective film is deposited on the entire surface.

In the interconnection structure and fabrication method as described above, as in the first embodiment, the stacked film of the barrier metal layer 18 which prevents the reaction between Cu and Al and the barrier metal layer 19 which increases the fluidity of Al with respect to the barrier metal layer 18 is formed between the Cu film 14-2 of the first metal interconnection layers (Cu interconnections) M1A and M1B and the AlCu(0.5%) 20 of the second metal interconnection layers (Al-based interconnections) M2A and M2B. Accordingly, it is possible to prevent the reaction between Al and Cu when the AlCu(0.5%) 20 is formed at a high temperature, and improve the burying properties of the AlCu(0.5%) 20.

Also, in the second embodiment, immediately after the first metal interconnection layers (Cu interconnections) are buried in the interconnection trenches 12A and 12B, the barrier metal layers 22A and 22B serving as films for preventing oxidation and diffusion of Cu are respectively formed on the first metal interconnection layers M1A and M1B. Accordingly, the time during which the surfaces of the first metal interconnection layers M1A and M1B are exposed is shorter than that in the first embodiment in which the barrier metal layer 18 is formed after the formation of the SiN film 15, second interlayer dielectric film 16, and holes 17A and 17B. This makes the first metal interconnection layers M1A and M1B hard to oxidize, and reduces the amount of Cu atoms which move into the etching stopper film 23 and interlayer dielectric film 16 when they are formed.

In addition, since the barrier metal layers 22A and 22B having a thickness of 15 nm or more are formed on the first metal interconnection layers M1A and M1B, it is possible to decrease the film thickness of the barrier metal layer 18 or form the barrier metal layer 19 alone. Also, when the AlCu(0.5%) 20 is formed at a high temperature, the elevation of the first metal interconnection layers M1A and M1B can be prevented by mechanically pressing them by the barrier metal layers 22A and 22B. Furthermore, it is possible to prevent shrinkage by heat dissipation after the high-temperature film formation from applying strain to the interlayer dielectric films 12 and 16 and etching stopper film 23 in the periphery, thereby preventing deterioration of the reliability by stress migration or the like.

### (Application)

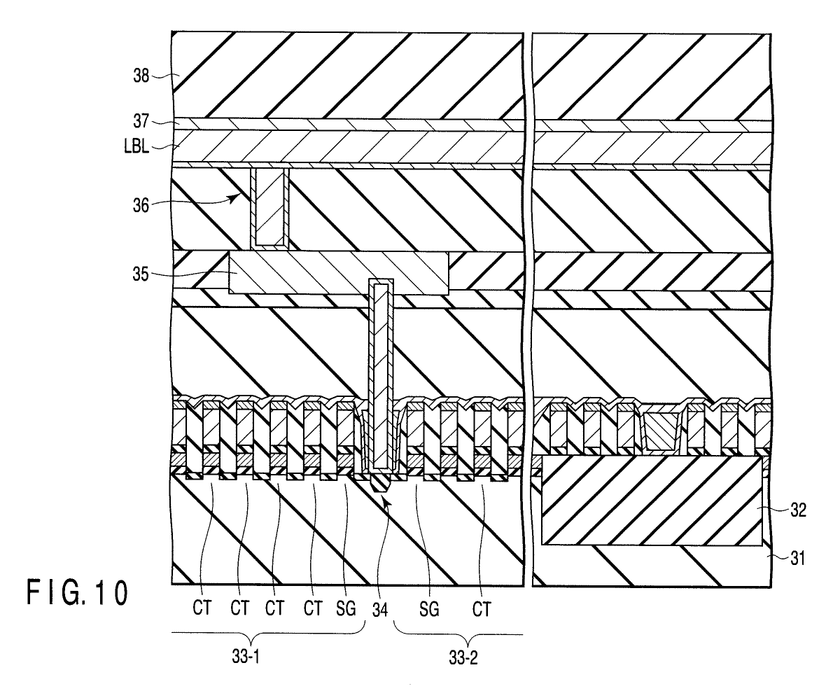

FIG. 10 is a sectional view showing an application of the interconnection structures explained in the first and second embodiments, in which a memory cell portion of a NAND flash memory is illustrated. An element isolation insulating film 32 is formed in the major surface of a semiconductor substrate 31. NAND strings 33-1 and 33-2 are formed on the major surface of the substrate 31 in an element region defined by the element isolation insulating film 32. In each of the NAND strings 33-1 and 33-2, the current paths of 16 or 32 cell transistors CT are connected in series. The cell transistors CT connect a plurality of memory cells in series such that adjacent memory cells share the source and drain. Each memory cell has an n-channel MOSFET structure in which a floating gate as a charge storage layer and a control gate are stacked. A first select gate is formed between one end of the series circuit and a bit line, and a second select gate is formed between the other end and a source line, thereby forming one NAND string.

In this example shown in FIG. 10, each select gate SG is formed by two transistors connected in series such that adjacent transistors share the source and drain. One of these two transistors is depleted by, e.g., ion-implanting an impurity in the channel region. An address signal for selecting a global bit line is supplied to the gate of one transistor, and an address signal for selecting a local bit line is supplied to the gate of the other transistor. Four adjacent NAND strings are selected in accordance with the position of the depleted transistor.

The select gate SG is connected to an interconnection 35 via a contact portion 34, and further connected to a local bit line LBL via a contact portion 36. The local bit line LBL has a structure corresponding to the first metal interconnection layers M1A and M1B shown in FIGS. 4 and 9.

An SiN film 37 as a film for preventing oxidation and diffusion of Cu is formed on the local bit line LBL, and an interlayer dielectric film 38 is formed on the SiN film 37. Although not shown, a hole for connecting the local bit line LBL and a global bit line GBL to be formed later is formed in the SiN film 37 and interlayer dielectric film 38. After that, a barrier metal layer for preventing the reaction between Cu and Al and a barrier metal layer for increasing the fluidity of Al with respect to the former barrier metal layer are formed on the interlayer dielectric film 38, on the side walls of the hole, and on the Cu film (local bit line LBL), and an Al—Cu film is so formed as to completely fill the hole.

Note that the present invention is not limited to the first and second embodiments described above, and various modifications can be made without departing from the spirit and scope of the invention. Various modifications will be explained below.

### (First Modification)

The first and second embodiments are explained by taking an example in which each of the barrier metal layers 13, 18, 19, 22A, and 22B has a single-layered structure. However, each barrier metal layer may also have a stacked structure.

### (Second Modification)

In the second embodiment, the third barrier metal layer 18 is formed on the second interlayer dielectric film 16, on the side walls of the holes 17A and 17B, and on the second barrier metal layers 22A and 22B. However, the same effect can be obtained by forming the fourth barrier metal layer 19 without forming the third barrier metal layer 18, and then forming the AlCu(0.5%) 20.

### (Third Modification)

The first and second embodiments are explained by taking an example in which the film formation temperature when Al is buried in the holes 17A and 17B is about 400° C. However, the film formation temperature is applicable to the temperature range of 325° C. to 450° C. 325° C. is the lower limit temperature at which Al is fluidized and buried. 450° C. is set from the film formation temperature of the interlayer dielectric film 16 formed immediately above the Cu film 14. This dielectric film immediately above the Cu film 14 prevents oxidation and diffusion of Cu. If the temperature in the subsequent step is made higher than the film formation temperature, the dielectric film changes its properties, Cu leaks due to the stress difference between Cu and the dielectric film, or Cu oxidizes. Therefore, 450° C. is the upper limit temperature.

### (Fourth Modification)

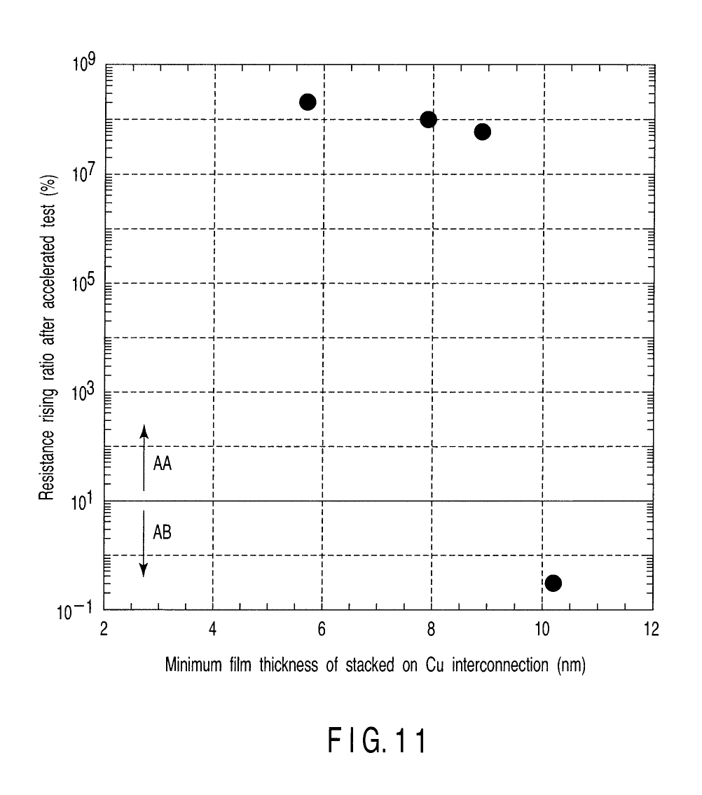

The above embodiments are explained by taking an example in which the film thickness of each of the barrier metal layers 18 and 19 is about 15 nm. As shown in FIG. 11, however, this stacked film must have a thickness of at least 10 nm regardless of the film formation temperature described above. FIG. 11 shows the relationship between the minimum film thickness of the stacked film on the Cu interconnection and the resistance rising ratio after an accelerated test. In this test, a plurality of contact (via contact) structures including the first metal interconnection layers M1A and M1B and second metal interconnection layers M2A and M2B as shown in FIG. 4 were formed, and a via chain obtained by electrically connecting these contact structures in series was used as a sample. A plurality of samples different in stacked film thickness were prepared, and an accelerated test was conducted on these samples to check the resistance rising ratio of the via chain.

The determination criterion of the resistance rising ratio is 10% because it is empirically known that a defective contact occurs due to a physical factor at 10%. That is, a product whose resistance rising ratio indicated by an arrow AA is 10% or more is a defective product, and a product whose resistance rising ratio indicated by an arrow AB is 10% or less is a good product. When the film thickness of the stacked film is about 5.7 nm, about 7.8 nm, and about 8.9 nm, the resistance rising ratio extremely increases to cause a defective connection. On the other hand, when the film thickness of the stacked film is about 10.2 nm, the resistance rising ratio extremely decreases, so a low-resistance, high-quality connection is obtained.

### (Fifth Modification)

The above embodiments are explained by taking an example in which a Ta film is used as the barrier metal layer 18 for preventing the reaction between Cu and Al. However, it is also possible to use a Ti film, a Ti compound film, a Ta compound film, a W compound film, or a stacked film of these films.

### (Sixth Modification)

The above embodiments are explained by taking an example in which a Ti film is used as the barrier metal layer 19. However, it is also possible to use a Ti compound film, an Nb film, an Nb compound film, or a stacked film of these films.

As described above, a semiconductor device according to the first mode of the present invention comprising an insulating film formed on a substrate, a Cu interconnection buried on a first barrier metal layer in a trench formed in a surface of the insulating film, an interlayer dielectric film formed on the insulating film, the first barrier metal layer, and the Cu interconnection, and including a hole in a position corresponding to the Cu interconnection, an Al-based interconnection electrically connected to the Cu interconnection in the hole of the interlayer dielectric film, and a stacked film interposed at least between the Cu interconnection and the Al-based interconnection, and comprising a second barrier metal layer to prevent a reaction between Cu and Al, and a third barrier metal layer to increase a fluidity of Al with respect to the second barrier metal layer.

Desirable modes are as follows.
(1) The opening diameter of the hole in the interlayer dielectric film is smaller than 0.3 μm, and the ratio (A/B) of a thickness A of the interlayer dielectric film to an opening diameter B is larger than 1.0.
(2) The film thickness of the stacked film on the Cu interconnection is larger than 10 nm.
(3) The insulating film formed on the substrate is an interlayer dielectric film formed on a semiconductor substrate.
(4) The first barrier metal layer comprises a Ta film having a thickness of at least 10 nm.
(5) The second barrier metal layer is a Ti film, a Ti compound film, a Ta film, a Ta compound film, a W compound film, or a stacked film of these films.
(6) The third barrier metal layer is a Ti film, a Ti compound film, an Nb film, an Nb compound film, or a stacked film of these films.

A semiconductor device fabrication method according to the second mode of the present invention comprising forming a Cu interconnection on a first barrier metal layer in a trench formed in an insulating film on a substrate, forming a film which prevents oxidation and diffusion of Cu on the insulating film, the first barrier metal layer, and the Cu interconnection, forming an interlayer dielectric film on the film which prevents oxidation and diffusion of Cu, forming a hole which exposes the Cu interconnection in positions, which correspond to the Cu interconnection, of the interlayer dielectric film and the film which prevents oxidation and diffusion of Cu, forming, in the hole, a second barrier metal layer to prevent a reaction between Cu and Al, forming a third barrier metal layer to increase a fluidity of Al with respect to the second barrier metal layer, on a surface of the second barrier metal layer in the hole, forming Al at a temperature of 325° C. to 450° C. such that Al is buried on the third barrier metal layer in the hole, and forming an Al-based interconnection by patterning the Al-based film, the third barrier metal layer, and the second barrier metal layer.

Desirable modes are as follows.
(1) The substrate is a semiconductor substrate, and the method further comprises forming a semiconductor element and a lower interconnection layer on the semiconductor substrate, and forming an interlayer dielectric film serving as an insulating isolation layer of the semiconductor element and the lower interconnection layer.
(2) The step of forming the Cu interconnection comprises sputtering a Ta film as the first barrier metal layer in the trench formed in the insulating film on the substrate, forming a first Cu film without exposure to the atmosphere, and forming a second Cu film on the first Cu film by plating.
(3) The second and third barrier metal layers are formed by bias sputtering or CVD.

A semiconductor device fabrication method according to the third mode of the present invention comprising forming a Cu interconnection on a first barrier metal layer in a trench formed in an insulating film on a substrate, forming, on the Cu interconnection, a second barrier metal layer to prevent oxidation and diffusion of Cu, forming an interlayer dielectric film on the second barrier metal layer and the insulating film, forming a hole which exposes the second barrier metal layer in positions, which correspond to the Cu interconnection, of the second barrier metal layer and the interlayer dielectric film, forming, in the hole, a third barrier metal layer to increase a fluidity of Al, forming Al at a temperature of 325° C. to 450° C. such that Al is buried on the third barrier metal layer in the hole, and forming an Al-based interconnection by patterning the Al-based film and the third barrier metal layer.

Desirable modes are as follows.
(1) The method further comprises forming, in the hole, a fourth barrier metal layer to prevent a reaction between Cu and Al, between forming the hole which exposes the Cu interconnection and forming, in the hole, the third barrier metal layer to increase the fluidity of Al.
(2) The substrate is a semiconductor substrate, and the method further comprises forming a semiconductor element and a lower interconnection layer on the semiconductor substrate, and forming an interlayer dielectric film serving as an insulating isolation layer of the semiconductor element and the lower interconnection layer.
(3) The step of forming the Cu interconnection comprises sputtering a Ta film as the first barrier metal layer in the trench formed in the insulating film on the substrate, forming a first Cu film without exposure to the atmosphere, and forming a second Cu film on the first Cu film by plating.
(4) The third barrier metal layer is formed by bias sputtering or CVD.

In each embodiment of the present invention as described above, in a multilayered interconnection structure in which an Al-based interconnection formed at a high temperature is connected on a Cu interconnection, two or more barrier metal layers including a barrier metal layer which prevents the reaction between Cu and Al and a barrier metal layer having a high Al fluidity are formed on Cu. This makes it possible to obtain a semiconductor device and a method of fabricating the same which can suppress the rise in wiring resistance caused by the reaction between Cu and Al, and suppress deterioration of the reliability of the Cu interconnection caused by the elevation of Cu.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an insulating film formed on a substrate;
a Cu interconnection buried on a first barrier metal layer in a trench formed in a surface of the insulating film;
an interlayer dielectric film formed on the insulating film, the first barrier metal layer, and the Cu interconnection, and including a hole in a position corresponding to the Cu interconnection;
an Al-based interconnection electrically connected to the Cu interconnection in the hole of the interlayer dielectric film; and
a stacked film interposed at least between the Cu interconnection and the Al-based interconnection, and comprising a second barrier metal layer to prevent a reaction between Cu and Al, and a third barrier metal layer to increase a fluidity of Al with respect to the second barrier metal layer.

2. A device according to claim 1, wherein an opening diameter of the hole in the interlayer dielectric film is smaller than 0.3 μm, and a ratio (A/B) of a thickness A of the interlayer dielectric film to an opening diameter B is larger than 1.0.

3. A device according to claim 1, wherein a film thickness of the stacked film on the Cu interconnection is larger than 10 nm.

4. A device according to claim 1, wherein the insulating film formed on the substrate is an interlayer dielectric film formed on a semiconductor substrate.

5. A device according to claim 1, wherein the first barrier metal layer comprises a Ta film whose thickness is at least 10 nm.

6. A device according to claim 1, wherein the second barrier metal layer is a film selected from the group consisting of a Ti film, a Ti compound film, a Ta film, a Ta compound film, a W compound film, and a stacked film thereof.

7. A device according to claim 1, wherein the third barrier metal layer is a film selected from the group consisting of a Ti film, a Ti compound film, an Nb film, an Nb compound film, and a stacked film thereof.

8. A semiconductor device fabrication method comprising:
forming a Cu interconnection on a first barrier metal layer in a trench formed in an insulating film on a substrate;
forming a film which prevents oxidation and diffusion of Cu on the insulating film, the first barrier metal layer, and the Cu interconnection;
forming an interlayer dielectric film on the film which prevents oxidation and diffusion of Cu;
forming a hole which exposes the Cu interconnection in positions, which correspond to the Cu interconnection, of the interlayer dielectric film and the film which prevents oxidation and diffusion of Cu;
forming, in the hole, a second barrier metal layer to prevent a reaction between Cu and Al;
forming a third barrier metal layer to increase a fluidity of Al with respect to the second barrier metal layer, on a surface of the second barrier metal layer in the hole;
forming Al at a temperature of 325° C. to 450° C. such that Al is buried on the third barrier metal layer in the hole; and
forming an Al-based interconnection by patterning the Al-based film, the third barrier metal layer, and the second barrier metal layer.

9. A method according to claim 8, wherein the substrate is a semiconductor substrate, and the semiconductor device fabrication method further comprises forming a semiconductor element and a lower interconnection layer on the semiconductor substrate, and forming an interlayer dielectric film serving as an insulating isolation layer of the semiconductor element and the lower interconnection layer.

10. A method according to claim 8, wherein the step of forming a Cu interconnection comprises sputtering a Ta film as the first barrier metal layer in the trench formed in the insulating film on the substrate, forming a first Cu film without exposure to the atmosphere, and forming a second Cu film on the first Cu film by plating.

11. A method according to claim 8, wherein the second barrier metal layer and the third barrier metal layer are formed by one of bias sputtering and CVD.

12. A semiconductor device fabrication method comprising:
forming a Cu interconnection on a first barrier metal layer in a trench formed in an insulating film on a substrate;
forming, on the Cu interconnection, a second barrier metal layer to prevent oxidation and diffusion of Cu;
forming an interlayer dielectric film on the second barrier metal layer and the insulating film;
forming a hole which exposes the second barrier metal layer in positions, which correspond to the Cu interconnection, of the second barrier metal layer and the interlayer dielectric film;
forming, in the hole, a third barrier metal layer to increase a fluidity of Al;
forming Al at a temperature of 325° C. to 450° C. such that Al is buried on the third barrier metal layer in the hole; and
forming an Al-based interconnection by patterning the Al-based film and the third barrier metal layer.

13. A method according to claim 12, further comprising forming, in the hole, a fourth barrier metal layer to prevent a reaction between Cu and Al, between forming the hole which exposes the Cu interconnection and forming, in the hole, the third barrier metal layer to increase the fluidity of Al.

14. A method according to claim 12, in which the substrate is a semiconductor substrate, and which further comprises forming a semiconductor element and a lower interconnection layer on the semiconductor substrate, and forming an interlayer dielectric film serving as an insulating isolation layer of the semiconductor element and the lower interconnection layer.

15. A method according to claim 12, wherein forming the Cu interconnection comprises sputtering a Ta film as the first barrier metal layer in the trench formed in the insulating film on the substrate, forming a first Cu film without exposure to the atmosphere, and forming a second Cu film on the first Cu film by plating.

16. A method according to claim 12, wherein the third barrier metal layer is formed by one of bias sputtering and CVD.
